(19) United States
(12) Patent Application Publication
(10) Pub. No.: US 2008/0043882 A1
(43) Pub. Date: Feb. 21, 2008

(54) WIRELESS COMMUNICATION METHOD AND APPARATUS FOR PERFORMING HYBRID TIMING AND FREQUENCY OFFSET FOR PROCESSING SYNCHRONIZATION SIGNALS

(75) Inventors: Guodong Zhang, Farmingdale, NY (US); Allan Yingming Tsai, Boonton, NJ (US)

Correspondence Address: VOLPE AND KOENIG, P.C.;DEPT. ICC, UNITED PLAZA, SUITE 1600, 30 SOUTH 17TH STREET, PHILADELPHIA, PA, 19103, US

(73) Assignee: INTERDIGITAL TECHNOLOGY CORPORATION, Wilmington, DE (US)

(21) Appl. No.: 11/828,146

(22) Filed: Jul. 25, 2007

Related U.S. Application Data
(60) Provisional application No. 60/839,070, filed on Aug. 21, 2006.
(60) Provisional application No. 60/845,029, filed on Sep. 15, 2006.

(51) Int. Cl. H03K 9/00

(52) U.S. Cl. 375/316

(57) ABSTRACT

The present invention is related to a receiver having a plurality of antennas for receiving and performing hybrid timing and frequency offset on at least one signal that includes at least one synchronization channel (SCH) symbol having a plurality of time domain repetitive blocks. The receiver further includes an auto-correlation unit that outputs an auto-correlation result and the power of the received signal, a coarse timing detection unit that generates a coarse timing metric, a frequency offset estimation unit that generates a coarse frequency offset metric based on the coarse timing metric and the received signal, a frequency offset compensation unit that generates a compensated version of the received signal, and a fine tuning detection unit that generates a fine tuning detection metric based on a sample of the compensated version of the received signal that is cross-correlated with a primary synchronization channel (P-SCH) code sequence.

### CROSS REFERENCE TO RELATED APPLICATIONS

This application claims the benefit of U.S. Provisional Application No. 60/839,070 filed Aug. 21, 2006 and U.S. Provisional Application No. 60/845,029 filed Sep. 15, 2006, which are incorporated by reference as if fully set forth.

This application is also related to co-pending U.S. patent application Ser. No. 11/611,510, filed on Dec. 15, 2006.

### FIELD OF INVENTION

The present invention relates to a wireless communication receiver. More particularly, the present invention relates to a receiver that performs hybrid timing and frequency offset for processing synchronization signals in an evolved universal terrestrial radio access (E-UTRA) system.

### BACKGROUND

In order to keep the technology competitive for a much longer time period, both the Third Generation Partnership Project (3GPP) and 3GPP2 are considering long term evolution (LTE), in which evolution of radio interface and network architecture are necessary.

Currently, orthogonal frequency division multiple access (OFDMA) is adopted for the downlink of evolved UTRA. When a wireless transmit/receive unit (WTRU) powers on in the evolved UTRA system, (whose downlink is OFDMA based), the WTRU needs to synchronize the frequency, frame timing and the fast Fourier transform (FFT) symbol timing with the (best) cell, and identify the cell identity (ID) as well. This process is called cell search.

The synchronization channel and cell search process for OFDMA-based downlink are currently being studied in evolved UTRA (E-UTRA). It is desirable to define a synchronization channel that is a common for all cells in the system. A downlink synchronization channel (SCH) is transmitted using a 1.25 MHz bandwidth regardless of the entire bandwidth of the system. In this way, the same SCH is mapped to the central part of transmission bandwidth. FIG. 1 shows a downlink SCH 105 with a 1.25 MHz bandwidth occupied by two (2) 0.625 MHz tones T1 and T2. The same SCH 105 is mapped to the central portion of all of the system transmission bandwidths, (e.g., 20 MHz, 15 MHz, 10 MHz, 5 MHz, 2.5 MHz and 1.25 MHZ).

In the prior art, a primary synchronization channel (P-SCH) symbol contains time domain repetition blocks, which are generated by mapping the synchronization sequence directly onto subcarriers in an equal-spaced manner. That is, in order to generate K repetition blocks in time domain, every K^{th} subcarrier is used in the frequency domain for the synchronization channel. It is already known that a P-SCH symbol with two repetition blocks will generate plateau in timing detection, and larger number of repetitions (>2) will eliminate the plateau. However, the signal-to-noise ratio (SNR) of P-SCH symbols decreases as the number of repetitions increases, which in turns degrades the detection performance. To address the issue, it is desirable to improve generation of the P-SCH symbol for E-UTRA systems.

### SUMMARY

The present invention is related to a new primary synchronization channel structure and corresponding receiver processing for E-UTRA systems. The present invention solves the problem of synchronization performance loss yielded by cross-correlation with a large frequency offset or yielded by the inaccurate timing acquisition by auto-correlation based detection.

In one embodiment, the present invention provides a receiver having a plurality of antennas for receiving and performing hybrid timing and frequency offset on at least one signal that includes at least one synchronization channel (SCH) symbol having a plurality of time domain repetitive blocks. The receiver further includes an auto-correlation unit that outputs an auto-correlation result and the power of the received signal, a coarse timing detection unit that generates a coarse timing metric, a frequency offset estimation unit that generates a coarse frequency offset metric based on the coarse timing metric and the received signal, a frequency offset compensation unit that generates a compensated version of the received signal, and a fine tuning detection unit that generates a fine tuning detection metric based on a sample of the compensated version of the received signal that is cross-correlated with a P-SCH code sequence.

### BRIEF DESCRIPTION OF THE DRAWINGS

A more detailed understanding of the invention may be had from the following description of a preferred embodiment, given by way of example and to be understood in conjunction with the accompanying drawings wherein:

FIG. 1 shows a SCH defined for 1.25 MHz and centered in the middle of the available bandwidth;

FIG. 2 shows a primary synchronization channel structure in accordance with the present invention;

FIGS. 3 and 4 show orthogonal frequency division multiplexing (OFDM) primary synchronization symbols containing four time domain repetition and symmetrical blocks;

FIG. 5 shows a block diagram of a receiver that processes primary synchronization symbols in accordance with the present invention; and

FIG. 6 is a flow diagram of a method implemented by the receiver of FIG. 5.

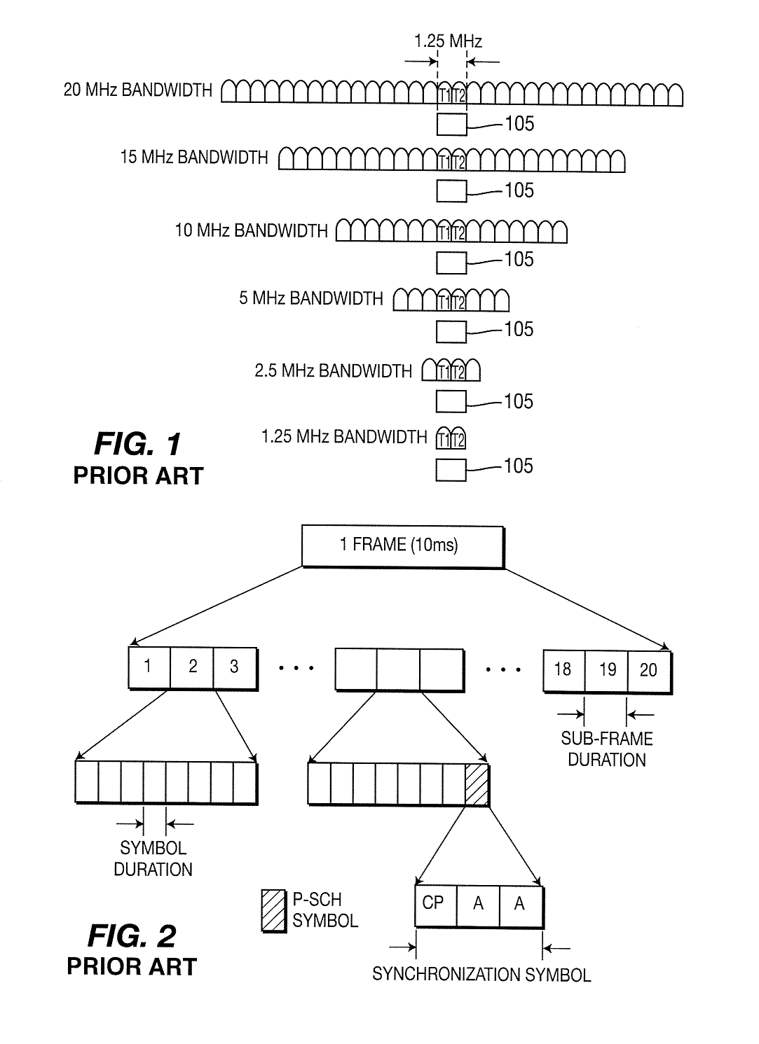

### DESCRIPTION OF THE PREFERRED EMBODIMENTS

When referred to hereafter, the terminology “wireless transmit/receive unit (WTRU)” includes but is not limited to a user equipment (UE), a mobile station, a fixed or mobile subscriber unit, a pager, a cellular telephone, a personal digital assistant (PDA), a computer, or any other type of user device capable of operating in a wireless environment. When referred to hereafter, the terminology “base station” includes but is not limited to a Node-B, a site controller, an access point (AP), or any other type of interfacing device capable of operating in a wireless environment. In this invention, we propose a new way to generate the synchronization symbol for E-UTRA systems to overcome the SNR loss problem.

As disclosed in commonly assigned U.S. patent application Ser. No. 11/611,510, entitled “Synchronization Channel for OFDMA Based Evolved UTRA Downlink”, filed on Dec. 15, 2006, a code sequence is fed into a Discrete Fourier Transform (DFT) first, and then the outputs of the DFT are mapped to the center chunk of subcarriers, (i.e., consecutive central subcarriers), to generate a primary synchronization symbol.

In order to generate N repetition blocks in time domain, N identical (except possibly sign reversed) sequences +A, −A (or B, −B where B is defined as a symmetrical form of A), are each precoded by DFT and mapped to localized subcarriers in the same way as disclosed in U.S. patent application Ser. No. 11/611,510. Primary synchronization symbols are generated after IDFT.

FIG. 2 shows a conventional primary synchronization channel structure.

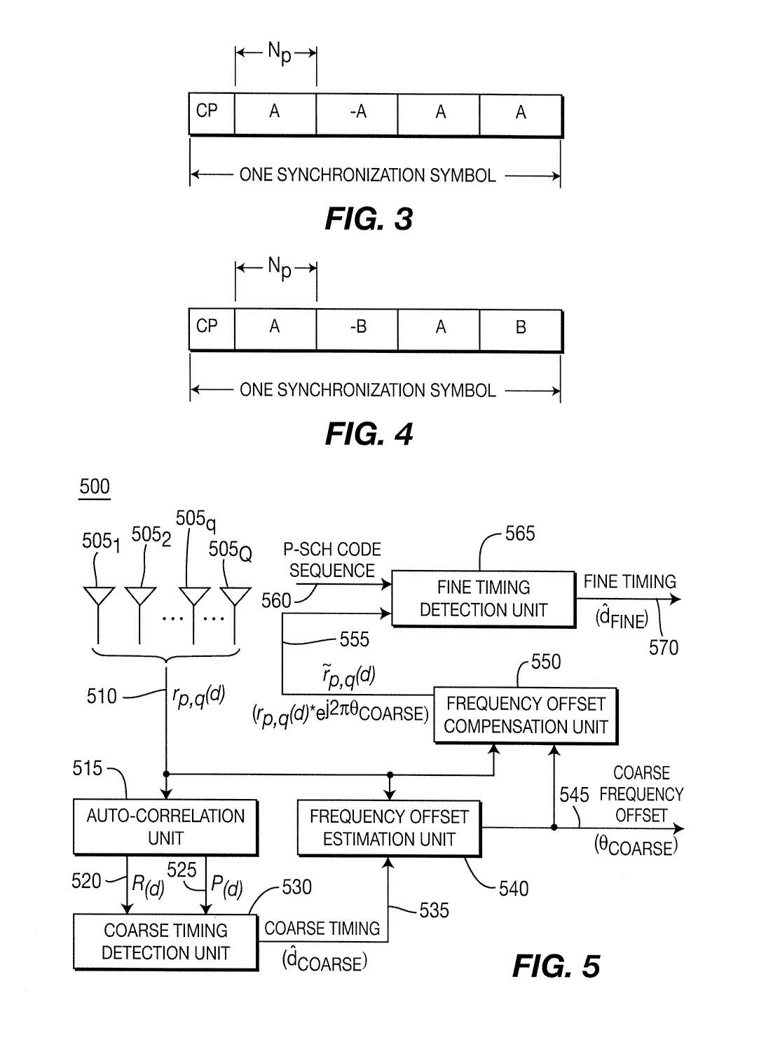

FIG. 3 shows an example of an OFDM primary synchronization symbol containing four time domain repetition blocks, whereby the time domain pattern is equal to [A −A A A] and A is a sequence with the length of N/4, as is disclosed in commonly assigned U.S. patent application Ser. No. 11/611,510. A cyclic prefix (CP) is attached to the beginning of each OFDM symbol to prevent inter-symbol-interference (ISI) in an OFDMA system.

In another approach shown in FIG. 4, the time domain pattern is equal to [A −B A B], where B is defined as a symmetrical form of A, as is disclosed in commonly assigned U.S. patent application Ser. No. 11/611,510.

Generalized chip like (GCL) sequences and other code sequences with good auto-correlation property can be used to generate synchronization sequence A. Using GCL sequences and other code sequences are disclosed in commonly assigned U.S. patent application Ser. No. 11/611,510.

FIG. 5 shows a block diagram of a receiver 500 that performs hybrid timing and frequency offset detection for processing synchronization signals on a channel generated by an E-UTRA system. The receiver 500 may be located in a WTRU. The receiver 500 includes a plurality of antennas 505₁, 505₂, . . . , 505_{q}, . . . , 505_{Q}, an auto-correlation unit 515, a coarse timing detection unit 530, a frequency offset estimation unit 540, a frequency offset compensation unit 550 and a fine timing detection unit 565.

Referring to FIG. 5, the antennas 505₁, 505₂, . . . , 505_{q}, . . . , 505_{Q} receive at least one signal r_{p,q}(d) 510 that includes at least one synchronization channel (SCH) symbol having a plurality of time domain repetitive blocks. The received signal r_{p,q}(d) 510 corresponds to the p^{th} synchronization symbol of the q^{th} antenna received during a sample timing index d. The sample timing index d represents a unit of sample time during which downlink signals are transmitted and received.

The auto-correlation unit 515 receives the signal r_{p,q}(d) 510 and outputs an auto-correlation result of r_{p,q}(d), denoted by R(d) 520 and the power of the received signal r_{p,q}(d), denoted by P(d) 525. The auto-correlation unit 515 calculates auto-correlation of the received signal r_{p,q}(d) 510 as follows:

1) For P-SCH signals received by the antennas 505 with an L repetitive pattern, the subvector r_{p,q}^{A,K}(d)=[r_{q}(d), . . . , r_{q}(d+K−1)]^{T} is defined as the column subvector of a received signal with vector length K and starting from sample timing index d, where [ ]^{T} is the transport operation. For an L repetitive pattern, the auto-correlation of the received q^{th} synchronization signal samples r_{q}(d), denoted as R(d), is given by

$$R ( d ) = {\sum }_{p = 1}^{P} {\sum }_{q = 1}^{Q} {\vert {\sum }_{k = 0}^{{N}_{CP} + \frac{N}{2} - 1} b ( l ) {r}_{p , q} ( k + d ) {r}_{p , q}^{*} ( k + d + \frac{N}{2} ) \vert}^{2} , \qquad Equation ( 1 )$$

where P is the number of synchronization symbols used for averaging, Q is the number of receive antennas and N is the P-SCH time domain symbol size. The operator ( )* denotes Hermitian operation, b(l)=a(l)a(l+1), l=0, 1, . . . , L−2, d is the sample timing index of received samples r_{p,q}(d) in a search window N_{W}, and N_{CP} is the number of samples in a cyclic prefix. The search window N_{W} is the number of consecutive samples of received signals that require processing by the receiver 500. During the length of search window N_{W}, auto-correlation in Equation 1 is performed (N_{W}−N) times to detect the timing.

2) Similarly, for L repetitive with symmetrical pattern, (e.g., see FIG. 4), define r_{p,q}^{B,K}(d)=[r_{q}(d+K−1), . . . , r_{q}(d)]^{T} as the symmetrical subvector of a received signal with vector length K and starting from sample timing index d. The auto-correlation of the received q^{th} synchronization signal samples r_{p,q}(d), denoted as R_{L}^{rep}^{_{—}}^{sym}(d), is given by

$${R}_{L}^{rep\_sym} ( d ) = \vert {\sum }_{q = 1}^{Q} {\sum }_{l = 0}^{L - 2} b ( l ) ( {r}_{q}^{A , \frac{N}{L}} ( d + l \frac{N}{L} ) ) {r}_{q}^{B , \frac{N}{L}} ( d + ( l + 1 ) \frac{N}{L} ) \vert \qquad Equation ( 2 )$$

3) The power of the received synchronization symbol, denoted as P(d), is given by:

$$P ( d ) = {\sum }_{p = 1}^{P} {\sum }_{q = 1}^{Q} {\vert {\sum }_{k = 0}^{{N}_{CP} + \frac{N}{2} - 1} {r}_{p , q} ( k + d + \frac{N}{2} ) {r}_{p , q}^{*} ( k + d + \frac{N}{2} ) \vert}^{2} . \qquad Equation ( 3 )$$

The auto-correlation unit 515 outputs R(d) 520 and P(d) 525, which are input into the coarse timing detection unit 530 for generation of a coarse timing \hat{d}_{coarse} 535. The coarse timing detection unit 530 calculates a timing detection metric as the ratio between R(d) and P(d), and compares the timing detection metric R(d)/P(d) to a detection threshold η.

If the value of R(d)/P(d) is greater than or equal to η, then sample timing index d is considered as a candidate detected timing. The receiver 500 will continue to process the next sample in the search window N_{W}.

If the value of R(d)/P(d) is less than η, then sample timing index d is discarded. The receiver 500 will continue to process the next sample in the search window N_{W}.

Among all candidate detection timing in the search window N_{W}, the sample timing index d that yields the largest R(d)/P(d) is chosen as the coarse detected timing:

$${\hat{d}}_{coarse} = {arg max}_{d} \{ \frac{R ( d )}{P ( d )} > η , 0 \leq d \leq {N}_{W} \} . \qquad Equation ( 4 )$$

The coarse timing \hat{d}_{coarse} 535 and the received signal r_{p,q}(d) 510 are fed to the frequency offset estimation unit 540 to generate a coarse frequency offset θ_{coarse} 545 The frequency offset estimation unit 540 performs a coarse frequency estimate of the received sync signals by performing the following steps:

1) Plug the value of \hat{d}_{coarse} into auto-correlation output in Equation 1 or 2.

2) Then, the frequency offset estimator 535 calculates the coarse frequency offset θ_{coarse} 540 as the frequency offset of the auto-correlation at the detected coarse sample timing \hat{d}_{coarse}:

$${θ}_{coarse} = \frac{{f}_{s}}{π N} arg \{ - {\sum }_{p = 1}^{P} {\sum }_{q = 1}^{Q} {\sum }_{k = 0}^{\frac{N}{2} - 1} {r}_{p , q} ( k + {\hat{d}}_{coarse} ) {r}_{p , q}^{*} ( k + {\hat{d}}_{coarse} + \frac{N}{2} ) \} , \qquad Equation ( 5 )$$

where fₛ is the sampling frequency and arg{x} denotes the phase of complex value of x. The auto-correlation window size can be smaller than N/2 , (i.e., size of repetition of pattern), to reduce the complexity.

The coarse frequency offset θ_{coarse} 545 and the received signal r_{p,q}(d) 510 are fed to the frequency offset compensation unit 550 to generate a compensated received signal 555 that is given by:
\tilde{r}_{p,q}(d)=r_{p,q}(d)·e^{j2πθ}^{_{coarse}} Equation (6)

The compensated received signal \tilde{r}_{p,q}(d) 555 and a P-SCH sequence 560 c(d) are fed to the fine timing detection unit 565 to generate fine timing metric (\hat{d}_{fine}) 670. The fine timing detection unit 565 performs the following steps:

1) Each sample of compensated received signals \tilde{r}_{p,q}(d) is cross-correlated with P-SCH sequence c(d) in the search window. The output of cross-correlation operation can be expressed as:

$${R}_{f} ( d ) = {\sum }_{p = 1}^{P} {\sum }_{q = 1}^{Q} {\vert {\sum }_{k = ( m - 1 ) L}^{mL - 1} {c}^{*} ( k + d ) {\tilde{r}}_{p , q} ( d ) \vert}^{2} . \qquad Equation ( 7 )$$

2) Then, the fine timing detection unit calculates the fine timing detection metric, which equals to

$$\frac{{R}_{f} ( d )}{P ( d )} .$$

The sample timing index that yields the largest

$$\frac{{R}_{f} ( d )}{P ( d )}$$

that is no less than a threshold η is selected as the fine timing metric (\hat{d}_{fine}):

$${\hat{d}}_{fine} = {arg max}_{d} \{ \frac{{R}_{f} ( d )}{P ( d )} > η , 0 \leq d \leq {N}_{W} \} . \qquad Equation ( 8 )$$

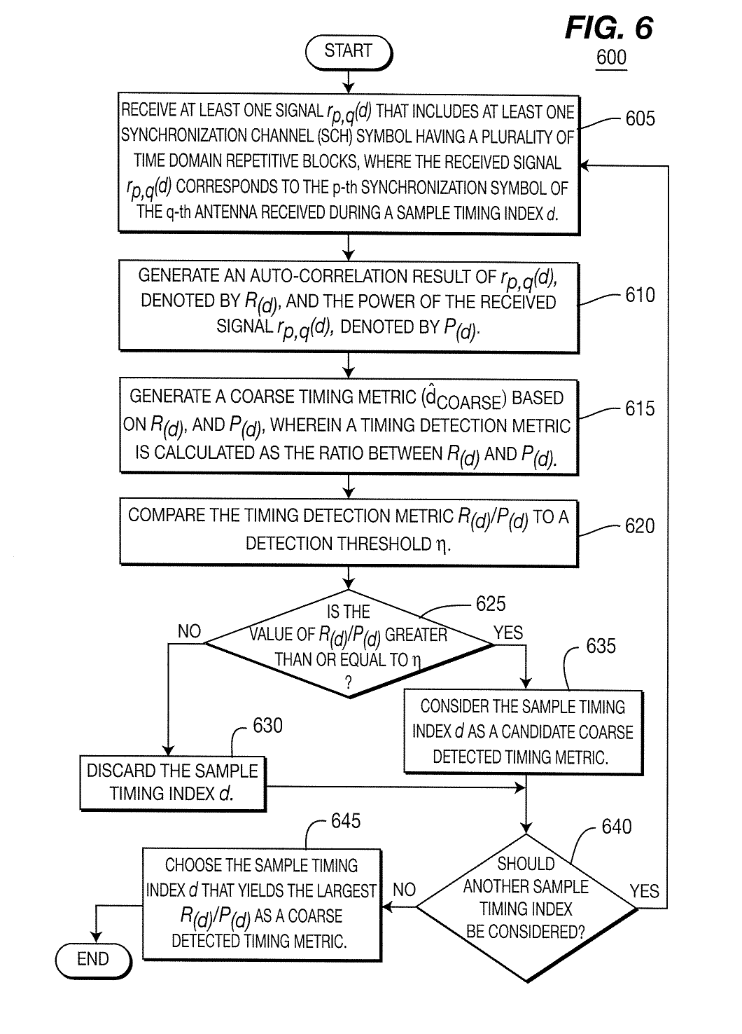

FIG. 6 is a flow diagram of a wireless communication method 600 implemented by the receiver 500 of FIG. 5, whereby hybrid timing and frequency offset detection is performed for processing synchronization signals on a channel generated by an E-UTRA system. In step 605, at least one signal r_{p,q}(d) is received that includes at least one synchronization channel (SCH) symbol having a plurality of time domain repetitive blocks, where the received signal r_{p,q}(d) corresponds to the p^{th} synchronization symbol of the q^{th} antenna during a sample timing index d. In step 610, an auto-correlation result of r_{p,q}(d) is generated, denoted by R(d), and the power of the received signal r_{p,q}(d) is generated, denoted by P(d). In step 615, a coarse timing metric (\hat{d}_{coarse}) is generated based on R(d) and P(d), wherein a timing detection metric is calculated as the ratio between R(d) and P(d).

In step 620, the timing detection metric R(d)/P(d) is compared to a detection threshold η. If, in step 625, it is determined that the value of R(d)/P(d) is less than η, then sample timing index d is discarded (step 630). If, in step 625, it is determined that the value of R(d)/P(d) is greater than or equal to η, then the sample timing index d is considered as a candidate detected timing (step 635). If it is determined in step 640 that another sample timing index d is to be considered, the method 600 returns to step 605. Otherwise, the sample timing index d that yields the largest R(d)/P(d) is chosen as a coarse detected timing metric (step 645).

Although the features and elements of the present invention are described in the preferred embodiments in particular combinations, each feature or element can be used alone without the other features and elements of the preferred embodiments or in various combinations with or without other features and elements of the present invention. The methods or flow charts provided in the present invention may be implemented in a computer program, software, or firmware tangibly embodied in a computer-readable storage medium for execution by a general purpose computer or a processor. Examples of computer-readable storage mediums include a read only memory (ROM), a random access memory (RAM), a register, cache memory, semiconductor memory devices, magnetic media such as internal hard disks and removable disks, magneto-optical media, and optical media such as CD-ROM disks, and digital versatile disks (DVDs).

Suitable processors include, by way of example, a general purpose processor, a special purpose processor, a conventional processor, a digital signal processor (DSP), a plurality of microprocessors, one or more microprocessors in association with a DSP core, a controller, a microcontroller, Application Specific Integrated Circuits (ASICs), Field Programmable Gate Arrays (FPGAs) circuits, any other type of integrated circuit (IC), and/or a state machine.

A processor in association with software may be used to implement a radio frequency transceiver for use in a wireless transmit receive unit (WTRU), user equipment (UE), terminal, base station, radio network controller (RNC), or any host computer. The WTRU may be used in conjunction with modules, implemented in hardware and/or software, such as a camera, a video camera module, a videophone, a speakerphone, a vibration device, a speaker, a microphone, a television transceiver, a hands free headset, a keyboard, a Bluetooth® module, a frequency modulated (FM) radio unit, a liquid crystal display (LCD) display unit, an organic light-emitting diode (OLED) display unit, a digital music player, a media player, a video game player module, an Internet browser, and/or any wireless local area network (WLAN) module.

What is claimed is:

1. A receiver for performing hybrid timing and frequency offset detection for processing synchronization signals on a channel generated by an evolved universal terrestrial radio access (E-UTRA) system, the receiver comprising:
a plurality of antennas for receiving at least one signal r_{p,q}(d) that includes at least one synchronization channel (SCH) symbol having a plurality of time domain repetitive blocks, wherein the received signal r_{p,q}(d) corresponds to the p^{th} synchronization symbol of the q^{th} antenna during a sample timing index d; and
a fine tuning detection unit configured to generate a fine tuning detection metric (\hat{d}_{fine}) based on a sample of a compensated version of the received signal r_{p,q}(d) that is cross-correlated with a primary synchronization channel (P-SCH) code sequence.

2. The receiver of claim 1 further comprising:
an auto-correlation unit configured to receive the signal r_{p,q}(d) and output an auto-correlation result of r_{p,q}(d), denoted by R(d), and the power of the received signal r_{p,q}(d), denoted by P(d).

3. The receiver of claim 2 further comprising:
a coarse timing detection unit configured to generate a coarse timing metric (\hat{d}_{coarse}) based on R(d) and P(d), wherein the coarse timing detection unit is further configured to calculate a timing detection metric as the ratio between R(d) and P(d), and compares the timing detection metric R(d)/P(d) to a detection threshold η.

4. The receiver of claim 3 wherein if the value of R(d)/P(d) is greater than or equal to η, then the sample timing index d is considered as a candidate detected timing and the receiver will continue to process the next sample in a search window N_{W}.

5. The receiver of claim 3 wherein if the value of R(d)/P(d) is less than η, then sample timing index d is discarded and the receiver will continue to process the next sample in the search window N_{W}.

6. The receiver of claim 3 wherein the sample timing index d that yields the largest R(d)/P(d) is chosen as a coarse detected timing metric.

7. The receiver of claim 3 further comprising:
a frequency offset estimation unit configured to generate a coarse frequency offset metric (θ_{coarse}) based on the coarse timing metric (\hat{d}_{coarse}) and the received signal r_{p,q}(d).

8. The receiver of claim 7 further comprising:
a frequency offset compensation unit electrically coupled to the frequency offset estimation unit and the fine timing detection unit for generating the compensated version of the received signal r_{p,q}(d).

9. The receiver of claim 8 wherein the compensated version of the received signal r_{p,q}(d) is generated based on the coarse frequency offset metric (θ_{coarse}) generated by the frequency offset estimation unit and the received signal r_{p,q}(d), wherein the compensated version of the received signal is denoted as \tilde{r}_{p,q}(d), where \tilde{r}_{p,q}(d)=r_{p,q}(d)·e^{j2πθ}^{_{coarse}}.

10. A wireless transmit/receive unit (WTRU) comprising the receiver of claim 1.

11. A receiver for performing hybrid timing and frequency offset detection for processing synchronization signals on a channel generated by an evolved universal terrestrial radio access (E-UTRA) system, the receiver comprising:
a plurality of antennas configured to receive at least one signal r_{p,q}(d) that includes at least one synchronization channel (SCH) symbol having a plurality of time domain repetitive blocks, wherein the received signal r_{p,q}(d) corresponds to the p^{th} synchronization symbol of the q^{th} antenna during a sample timing index d; and
an auto-correlation unit configured to receive the signal r_{p,q}(d) and outputs an auto-correlation result of r_{p,q}(d), denoted by R(d), and the power of the received signal r_{p,q}(d), denoted by P(d).

12. The receiver of claim 11 further comprising:
a fine tuning detection unit configured to generate a fine tuning detection metric (\hat{d}_{fine}) based on a sample of a compensated version of the received signal r_{p,q}(d) that is cross-correlated with a primary synchronization channel (P-SCH) code sequence.

13. The receiver of claim 12 further comprising:
a coarse timing detection unit configured to generate a coarse timing metric (\hat{d}_{coarse}) based on R(d) and P(d), wherein the coarse timing detection unit calculates a timing detection metric as the ratio between R(d) and P(d), and compares the timing detection metric R(d)/P(d) to a detection threshold η.

14. The receiver of claim 13 wherein if the value of R(d)/P(d) is greater than or equal to η, then the sample timing index d is considered as a candidate detected timing and the receiver will continue to process the next sample in a search window N_{W}.

15. The receiver of claim 13 wherein if the value of R(d)/P(d) is less than η, then sample timing index d is discarded and the receiver will continue to process the next sample in the search window N_{W}.

16. The receiver of claim 13 wherein the sample timing index d that yields the largest R(d)/P(d) is chosen as a coarse detected timing metric.

17. The receiver of claim 13 further comprising:
a frequency offset estimation unit configured to generate a coarse frequency offset metric (θ_{coarse}) based on the coarse timing metric (\hat{d}_{coarse}) and the received signal r_{p,q}(d).

18. The receiver of claim 17 further comprising:
a frequency offset compensation unit electrically coupled to the frequency offset estimation unit and the fine timing detection unit for generating the compensated version of the received signal r_{p,q}(d).

19. The receiver of claim 18 wherein the compensated version of the received signal r_{p,q}(d) is generated based on the coarse frequency offset metric (θ_{coarse}) generated by the frequency offset estimation unit and the received signal r_{p,q}(d), wherein the compensated version of the received signal is denoted as:
\tilde{r}_{p,q}(d)=r_{p,q}(d)·e^{j2πθ}^{_{coarse}}.

20. A wireless transmit/receive unit (WTRU) comprising the receiver of claim 11.

21. A wireless communication method for performing hybrid timing and frequency offset detection for processing synchronization signals on a channel generated by an evolved universal terrestrial radio access (E-UTRA) system, the method comprising:
receiving at least one signal r_{p,q}(d) that includes at least one synchronization channel (SCH) symbol having a plurality of time domain repetitive blocks, wherein the received signal r_{p,q}(d) corresponds to the p^{th} synchronization symbol of the q^{th} antenna during a sample timing index d;
generating an auto-correlation result of r_{p,q}(d), denoted by R(d), and the power of the received signal r_{p,q}(d), denoted by P(d);
generating a coarse timing metric (\hat{d}_{coarse}) based on R(d) and P(d), wherein a timing detection metric is calculated as the ratio between R(d) and P(d); and
comparing the timing detection metric R(d)/P(d) to a detection threshold η.

22. The method of claim 21 wherein if the value of R(d)/P(d) is greater than or equal to η, then the sample timing index d is considered as a candidate detected timing.

23. The method of claim 21 wherein if the value of R(d)/P(d) is less than η, then sample timing index d is discarded.

24. The method of claim 21 wherein the sample timing index d that yields the largest R(d)/P(d) is chosen as a coarse detected timing metric.

25. The method of claim 21 further comprising:
generating a fine tuning detection metric (\hat{d}_{fine}) based on a sample of a compensated version of the received signal r_{p,q}(d) that is cross-correlated with a primary synchronization channel (P-SCH) code sequence.

26. The method of claim 25 further comprising:
generating a coarse frequency offset metric (θ_{coarse}) based on the coarse timing metric (\hat{d}_{coarse}) and the received signal r_{p,q}(d).

27. The method of claim 26 wherein the compensated version of the received signal r_{p,q}(d) is generated based on the coarse frequency offset metric (θ_{coarse}) and the received signal r_{p,q}(d), wherein the compensated version of the received signal is denoted as \tilde{r}_{p,q}(d), where \tilde{r}_{p,q}(d)=r_{p,q}(d)·e^{j2πθ}^{_{coarse}}.
